(19) United States
(12) Patent Application Publication
(10) Pub. No.: US 2006/0060833 A1
(43) Pub. Date: Mar. 23, 2006

(54) Radiation-emitting optoelectronic component with a quantum well structure and method for producing it

(75) Inventors: Peter Bruckner, Tettnang (DE); Ferdinand Scholz, Ulm (DE); Barbara Neubert, Ulm (DE); Frank Habel, Freiberg (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 11/213,599

(22) Filed: Aug. 26, 2005

(30) Foreign Application Priority Data
Aug. 31, 2004 (DE) 10 2004 042 059.9
Feb. 8, 2005 (DE) 10 2005 005 635.0

(51) Int. Cl. H01L 29/06

(52) U.S. Cl. 257/13

(57) ABSTRACT

A radiation-emitting optoelectronic component with an active zone having a quantum well structure (5) containing at least one first nitride compound semiconductor material. The quantum well structure (5) is grown on at least one side facet (9) of a nonplanar structure (4) containing at least one second nitride compound semiconductor material. As a result of the quantum well structure (5) being grown onto a side facet (9), piezoelectric fields caused by lattice mismatches are advantageously reduced and the homogeneity of the quantum well structure (5) is improved.

### RELATED APPLICATIONS

This patent application claims the priority of German patent applications 102004042059.9 filed Aug. 31, 2004 and 102005005635.0 filed Feb. 8, 2005, the disclosure content of which is hereby incorporated by reference.

### FIELD OF THE INVENTION

The invention relates to a radiation-emitting optoelectronic component comprising an active zone having a quantum well structure containing at least one first nitride compound semiconductor material, and to a method for producing such a radiation-emitting optoelectronic component.

### BACKGROUND OF THE INVENTION

Heterostructures and quantum structures made of nitride compound semiconductors are often used in optoelectronic semiconductor components since a radiation emission in the short-wave visible and in the ultraviolet spectral region can be realized with these materials on account of their large electronic band gap. In ternary or quaternary nitride compound semiconductors, for example AlGaN, InGaN or InAlGaN, the electronic band gap can be varied by varying the composition of the semiconductor materials.

In contrast to conventional semiconductors, for example phosphides or arsenides, nitride compound semiconductors usually crystallize in the wurtzite structure. The preferred growth direction during the epitaxial production of semiconductor layers of this type is the c direction ([0001] direction).

In the production of heterostructures or quantum structures of nitride compound semiconductors, in which a plurality of layers having a different material composition are deposited one on top of the other, the problem exists that biaxial strains that lead to large piezoelectric fields occur on account of the comparatively large lattice constant differences among the nitride compound semiconductors. In a similar manner to that in the case of the known quantum confined Stark effect (QCSE), such piezoelectric fields may lead to a shift in the band edges of the conduction or valence band and to a spatial separation of electrons and holes produced by optical excitation, for example. This charge carrier separation reduces the recombination probability and thus, in particular, also the probability of stimulated emission of light.

Moreover, the optoelectronic properties in the case of nitride compound semiconductors containing indium are adversely affected not only by high piezoelectric fields but often also by spatial fluctuations in the composition, which is manifested for example in long charge carrier lifetimes, large luminescence line widths and a large wavelength shift between absorption and emission. A spatial fluctuation in the composition of the semiconductor material may arise in particular as a result of a spatial variation of the proportion of indium in an InGaN semiconductor. This is caused by comparatively low growth temperatures of approximately 700° C. to 800° C. during the epitaxial production of InGaN layers, which are caused by the low decomposition temperature of InN in comparison with GaN and AlN.

The high piezoelectric fields and the fluctuations in the composition make it more difficult to produce radiation-emitting optoelectronic components, for example LEDs or laser diodes, based on nitride compound semiconductors.

### SUMMARY OF THE INVENTION

One object of the invention is to provide an improved radiation-emitting optoelectronic component with an quantum well structure based on a nitride compound semiconductor which is distinguished in particular by comparatively low piezoelectric fields and/or small spatial composition fluctuations within the quantum well structure.

Another object is to provide an advantageous method for producing such a radiation-emitting component of this type.

This and other objects are attained in accordance with one aspect of the invention directed to a radiation-emitting optoelectronic component with an active zone having a quantum well structure containing at least one first nitride compound semiconductor material. The quantum well structure is grown on at least one side facet of a nonplanar structure containing at least one second nitride compound semiconductor material.

Growing a quantum well structure made of nitride compound semiconductors onto a side facet of a nonplanar structure has the advantage that the side facets constitute crystal faces in the case of which, on account of the anisotropic relationship between strain and piezoelectric effect, lower piezoelectric fields occur than would be the case for example in the conventional epitaxy of quantum well structures on a c face of a substrate. In this way, piezoelectric fields generated by strains are reduced and the disadvantageous effects of piezoelectric fields on the optical properties of the optoelectronic component as mentioned in the introduction to the description are reduced.

In the context of the invention, the designation quantum well structure encompasses any structure in which the charge carriers experience a quantization of their energy states as a result of confinement. In particular, the designation quantum well structure does not comprise any indication about the dimensionality of the quantization. It thus encompasses, inter alia, quantum wells, quantum wires and dots and any combination of these structures. The quantum well structure may contain for example a plurality of quantum films and barrier layers arranged between the quantum films.

The side facet is preferably a {1-101} crystal face, a {11-20} crystal face, a {1-100} crystal face or a {11-22} crystal face, and in particular not a {0001} crystal face.

The invention is particularly advantageous for quantum well structures which comprise an indium-containing III-V nitride compound semiconductor material, in particular a semiconductor material having the composition In_{1-x-y}AlₓGa_{y}N where 0≦x≦1, 0≦y≦1 and x+y<1.

Since the problem of the piezoelectric fields intensifies as the proportion of indium increases in the case of conventional epitaxy, the invention is particularly advantageous for semiconductor materials having the composition specified above in which the following holds true for the proportion of indium: 1−x−y>0.1, particularly preferably 1−x−y>0.2.

In the case of such indium-containing nitride compound semiconductors, growing the quantum well structure on side facets also has the advantage, besides avoiding piezoelectric fields, that the fluctuations in the indium proportion that often occur in conventional epitaxial production on account of altered surface migration properties on the side facets are reduced.

Since the emission wavelength of optoelectronic components based on InAlGaN semiconductors is shifted toward longer wavelengths as the proportion of indium increases, and the invention, for the reasons mentioned above, makes it possible to produce high-quality quantum well structures with a high proportion of indium, it is advantageously possible to realize optoelectronic components, in particular also laser diodes, in which the emitted radiation has a wavelength of more than 420 nm, particularly preferably more than 430 nm. In particular, the invention encompasses laser diodes based on In_{1-x-y}AlₓGa_{y}N which emit in the blue or green spectral region.

The nonplanar structure including the quantum well structure applied thereto is advantageously overgrown with a covering layer. The thickness of the covering layer is preferably chosen such that it has a planar surface. The covering layer serves, on the one hand, for protecting the quantum well structure from ambient influences and, on the other hand, also for impressing current into the optoelectronic component. In order to enable current to be impressed into the active zone, the nonplanar structure and the covering layer are preferably formed from electrically conductively doped semiconductor materials having an opposite conduction type. By way of example, the nonplanar structure may be n-doped and the covering layer p-doped, or, as an alternative, the nonplanar structure may be p-doped and the covering layer n-doped.

The nonplanar structure preferably comprises one or more strips. The strip or strips may have a triangular, trapezoidal or rectangular cross-sectional area, for example, transversely with respect to its or their longitudinal direction.

The strip or strips is or are preferably delimited by a first end face and a second end face in the strip longitudinal direction. The end faces are preferably parallel to one another and can thus advantageously form a laser resonator. The two end faces of the strip may be produced for example by an etching process, in particular a dry etching process. It is particularly advantageous if the first end face and the second end face are parallel crystal faces produced by epitaxial growth. The production outlay associated with the etching process can advantageously be obviated in this way.

In one embodiment of the invention, a plurality of strips arranged parallel to one another are provided. In this case, a laser resonator may be arranged in the longitudinal direction of the strips, as described above, or, as an alternative, also perpendicular to the longitudinal direction of the strips. In the latter case, the strips arranged parallel to one another may be arranged periodically in such a way that they form a DFB laser structure.

Instead of strips, the nonplanar structure in the case of the invention may also have other geometrical forms, in particular hexagonal structures such as, for example, hexagonal pyramids or truncated pyramids. Furthermore, cylindrical structures are also possible.

The active zone is preferably arranged between two waveguide layers. The waveguide layers may contain for example AlGaN or some other material which has a higher refractive index than the active zone. By way of example, the nonplanar structure may be applied to a first waveguide layer and the second waveguide layer may be applied to the covering layer, which preferably has a planar surface.

The optoelectronic component is preferably a laser diode. However, the invention also encompasses all forms of luminescence diodes containing quantum well structures, for example light emitting diodes (LEDs).

Another aspect of the present invention is directed to a method for producing a radiation-emitting optoelectronic component. An epitaxial surface is provided, to which a mask layer is applied. A nonplanar structure is produced on the epitaxial surface provided with the mask layer by growing on a nitride compound semiconductor material. A quantum well structure is grown onto at least one side facet of the nonplanar structure and a covering layer is subsequently applied.

The epitaxial surface may be the surface of a substrate, for example of a sapphire substrate. In order to facilitate the subsequent epitaxial growth of the nonplanar structure, the surface of a nitride compound semiconductor layer that was previously grown on a substrate, for example, is preferably used as the epitaxial surface. The material of the nitride compound semiconductor layer particularly preferably matches that of the nonplanar structure. It goes without saying that the epitaxial surface may also be the surface of a layer sequence made of a plurality of semiconductor layers which contains further functional semiconductor layers, for example a waveguide layer.

The mask layer is preferably formed from a silicon oxide or a silicon nitride or some other material which prevents the direct epitaxial growth of a nitride compound semiconductor. Furthermore, the mask layer contains at least one opening in which the epitaxial surface is uncovered for the growth of the nonplanar structure of the nitride compound semiconductor material.

The mask layer preferably contains a plurality of strip-type openings arranged parallel. The strip-type openings advantageously have a width of between 100 nm and 10 μm. The mutual distance between the strip-type openings is preferably between 100 nm and 200 μm.

The growth of the nonplanar structure and of the quantum well structure onto the epitaxial surface provided with the mask layer is preferably effected by means of metal organic vapor phase epitaxy (MOVPE). This deposition method is advantageous in particular for growing the quantum well structure onto the side facets of the nonplanar structure since, in comparison with directed deposition methods, for example molecular beam epitaxy, it enables a selective growth on the oblique and/or perpendicular surfaces, that is to say that, in particular, no semiconductor material nucleates on the masked regions.

A covering layer having a thickness such that it has a planar surface is preferably applied to the nonplanar structure including the quantum well structure. The requisite thickness depends, in particular, on the height of the nonplanar structure, which may be influenced for example by variation of the distances or the width of the strips. A planar covering layer facilitates the application of one or more further semiconductor layers, for example a waveguide layer or a layer for making electrical contact with the optoelectronic component.

### BRIEF DESCRIPTION OF THE DRAWINGS

FIG. 1 shows a schematic illustration of a cross section through a first exemplary embodiment of an optoelectronic component according to the invention,

FIG. 2 shows a schematic illustration of a cross section through an exemplary embodiment of a quantum well structure of an optoelectronic component according to the invention,

FIG. 3 shows a schematic illustration of a cross section through a second exemplary embodiment of an optoelectronic component according to the invention,

FIG. 4 shows a schematic perspective illustration of a third exemplary embodiment of an optoelectronic component according to the invention,

FIG. 5 shows a schematic illustration of a plan view of an exemplary embodiment of a mask layer which is used in a method according to the invention for producing an optoelectronic component,

FIG. 6 shows a schematic perspective illustration of a fourth exemplary embodiment of an optoelectronic component according to the invention,

FIG. 7 shows a schematic perspective illustration of a fifth exemplary embodiment of an optoelectronic component according to the invention,

FIG. 8 shows a schematic perspective illustration of a sixth exemplary embodiment of an optoelectronic component according to the invention, and

FIG. 9 shows a schematic perspective illustration of a seventh exemplary embodiment of an optoelectronic component according to the invention.

### DETAILED DESCRIPTION OF THE DRAWINGS

Identical or identically acting elements are provided with the same reference symbols in the Figures.

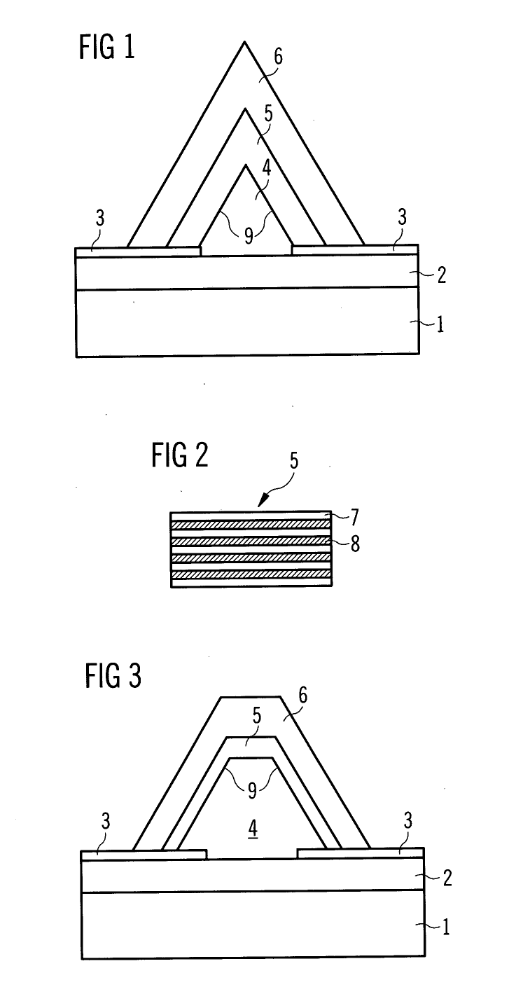

The first exemplary embodiment of an optoelectronic component according to the invention as illustrated in FIG. 1 contains a substrate 1, which is a sapphire substrate for example. A nitride compound semiconductor layer 2, for example a GaN layer, is applied to the substrate 1. A mask layer 3, containing a silicon oxide or a silicon nitride for example, is applied to partial regions of the semiconductor layer 2.

A nonplanar structure 4 made of a nitride compound semiconductor material is grown in the partial regions of the semiconductor layer 2 which are not covered by the mask layer 3. The nonplanar structure 4 may be formed for example from the same semiconductor material as the semiconductor layer 2. In particular, the semiconductor layer 2 and/or the nonplanar structure 4 may be formed from an n-doped nitride compound semiconductor, for example from Si-doped GaN.

The form of the nonplanar structure 4 may be influenced by the structure of the mask and the growth conditions during the growth of the nitride compound semiconductor material, in particular by a variation of the growth temperature. In the case of the exemplary embodiment shown in FIG. 1, the nonplanar structure 4 has a triangular cross-sectional area.

A quantum well structure 5 is grown onto the side facets 9 of the nonplanar structure 4. The quantum well structure 5 may contain in particular quantum films made of InGaN. The growth of the quantum well structure 5 onto the side facets 9 advantageously reduces piezoelectric fields in comparison with conventional epitaxy, which is usually effected on {0001} crystal faces. In this case, it is particularly advantageous if the side facets 9 are a {1-101} crystal face, a {11-20} crystal face, a {1-100} crystal face or a {11-22} crystal face.

A covering layer 6 is preferably applied to the quantum well structure 5, which covering layer may be, in particular, a p-doped semiconductor layer, for example Mg-doped GaN. By virtue of the fact that the covering layer 6 has the opposite conduction type to the nonplanar structure 4, a current can be impressed into the quantum well structure 5. In order to make contact with the optoelectronic component, it is possible, for example, to apply contacts (not illustrated) to the covering layer 6 and to partial regions of the semiconductor layer 2.

The quantum well structure 5 may contain quantum wells, quantum wires or quantum dots. As illustrated schematically in FIG. 2, it preferably contains a plurality of barrier layers 7, for example made of GaN, with quantum films 8, for example made of InGaN, situated in-between.

In the case of the exemplary embodiment of an optoelectronic component according to the invention as illustrated in FIG. 3, the nonplanar structure 4 has a trapezoidal cross-sectional area. As an alternative, it is possible, for example, also to provide a rectangular cross section for the nonplanar structure 4. Otherwise, the exemplary embodiment illustrated in FIG. 3 essentially corresponds to the exemplary embodiment illustrated in FIG. 1.

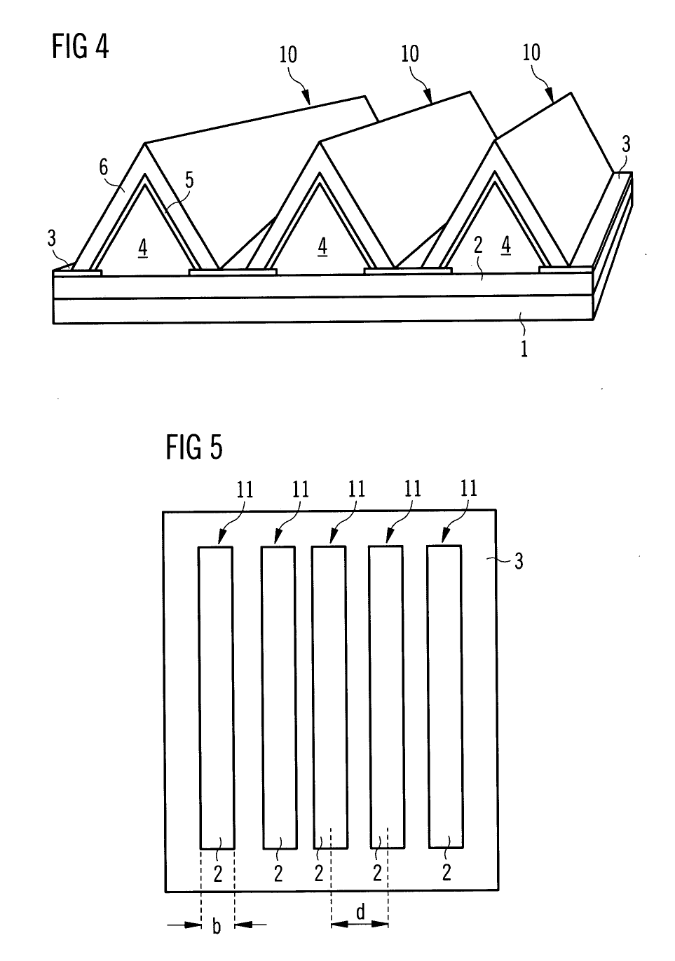

In the case of the exemplary embodiment of the invention as illustrated in FIG. 4, the nonplanar structure 4 has a plurality of strips 10 arranged parallel and each having a triangular cross-sectional area. Instead of the three strips 10 illustrated in FIG. 4, an optoelectronic component according to the invention may, of course, also comprise a larger number of such strips in order, in particular, to obtain a high intensity of the emitted radiation.

FIG. 5 illustrates a mask layer 3 which can be used in a method for producing an optoelectronic component according to the invention. The mask layer 3 has a plurality of strip-type openings 11 arranged parallel. The strip-type openings may be produced by patterning methods known per se, such as, for example, photolithography, and preferably have a width b of between 100 nm and 10 μm and a mutual on-center distance d of between 100 nm and 200 μm. The semiconductor material 2 is uncovered in the openings 11 of the mask layer, on which semiconductor material the nonplanar structure 4 can be grown epitaxially.

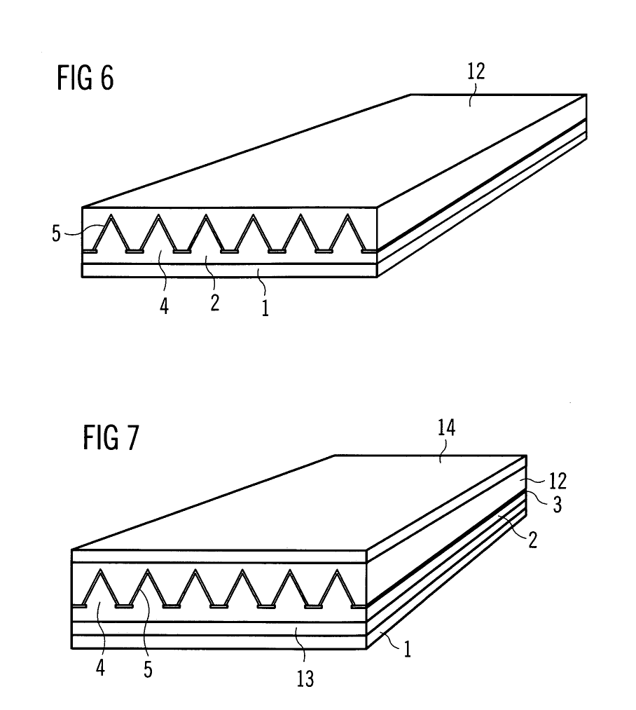

In the case of the exemplary embodiment of an optoelectronic component according to the invention as illustrated in FIG. 6, a covering layer 12 is applied, which has a planar surface. A planarization of the covering layer may be achieved by depositing the covering layer with a sufficient thickness. The requisite thickness may be reduced in particular by reducing the strip widths and the distances between the strips.

A planar covering layer 12 is advantageous particularly when, as in the case of the exemplary embodiment illustrated in FIG. 7, provision is made for embedding the active zone formed from the quantum well structure 5 in two waveguide layers 13, 14. The exemplary embodiment illustrated in FIG. 7 contains a first waveguide layer 13 deposited on the substrate 1, the semiconductor layer 2 being applied to the waveguide layer 13, the nonplanar structure 4 being grown on said semiconductor layer 2. A second waveguide layer 14 is applied to the planar covering layer 12. Through the waveguide formed from the waveguide layers 13, 14, the radiation emitted by the quantum well structure 5 is guided in the plane parallel to the waveguide layers 13, 14 and a comparatively high emission of the optoelectronic component is thus achieved in the lateral direction.

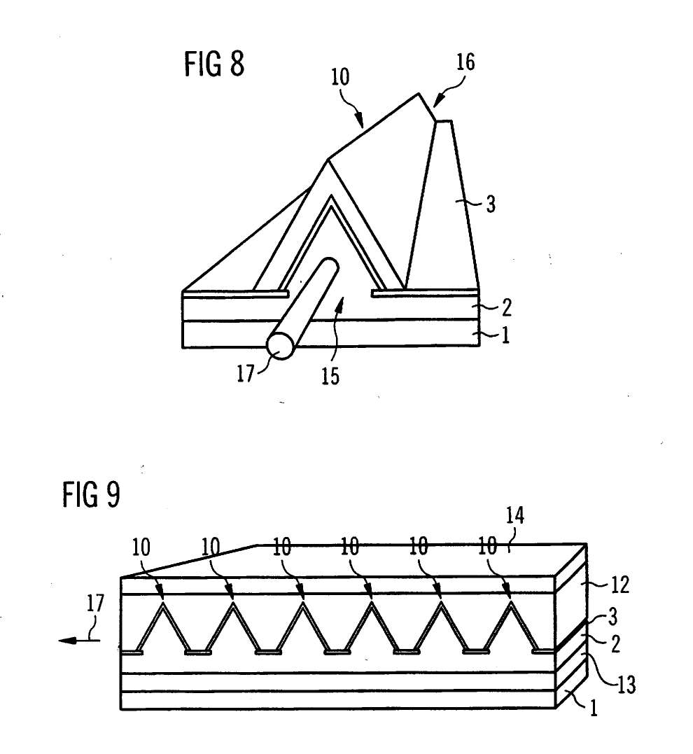

FIG. 8 shows a radiation-emitting optoelectronic component according to the invention, said component being a laser diode. The laser resonator is formed by two end faces 15, 16 of a strip 10. The laser diode emits laser radiation 17 parallel to the longitudinal direction of the strip 10. The two parallel end faces 15, 16 may be produced for example by means of an etching process, in particular a dry etching process. However, the end faces 15, 16 may advantageously also be parallel crystal faces that are produced directly during the epitaxial growth of the nonplanar structure 4. The etching process may advantageously be obviated in this case, thereby reducing the production outlay. It goes without saying that it is also possible for a plurality of strips 10 to be arranged next to one another in order to produce a multiple-beam laser diode.

In contrast to the exemplary embodiment illustrated in FIG. 8, a laser resonator may also be arranged transversely with respect to a longitudinal direction of the strips 10, as shown in FIG. 9.

As illustrated by the exemplary embodiment in FIG. 9, a plurality of strips 10 are arranged periodically in the direction perpendicular to the longitudinal direction of the strips in such a way that they form a DFB (Distribution Feedback) laser structure. In this case, laser radiation 17 is thus emitted perpendicularly to the longitudinal direction of the strips 10. As in the case of the optoelectronic component described above in connection with FIG. 7, the embedding of the active zone in waveguide layers 13, 14 is advantageous in the case of this component as well.

The invention is not restricted by the description on the basis of the exemplary embodiments. Rather, the invention encompasses any new feature and also any combination of features, which comprises in particular any combination of features in the patent claims, even if this feature or this combination itself is not explicitly specified in the patent claims or exemplary embodiments.

We I claim:

1. A radiation-emitting optoelectronic component comprising an active zone having a quantum well structure (5) containing at least one first nitride compound semiconductor material,
wherein
the quantum well structure (5) is grown on at least one side facet (9) of a nonplanar structure (4) containing at least one second nitride compound semiconductor material.

2. The radiation-emitting optoelectronic component as claimed in claim 1,
wherein
the quantum well structure (5) contains a plurality of quantum films (8) and barrier layers (7) arranged between the quantum films (8).

3. The radiation-emitting optoelectronic component as claimed in claim 1,
wherein
the side facet (9) is a crystal face which is not a {0001} crystal face.

4. The radiation-emitting optoelectronic component as claimed in claim 1,
wherein
the side facet (9) is a {1-101} crystal face, a {11-20} crystal face, a {1-100} crystal face or a {11-22} crystal face.

5. The radiation-emitting optoelectronic component as claimed in claim 1,
wherein
the quantum well structure (5) contains In_{1-x-y}AlₓGa_{y}N where 0≦x≦1, 0≦y≦1 and x+y<1 as first nitride compound semiconductor material.

6. The radiation-emitting optoelectronic component as claimed in claim 5,
wherein
1−x−y≧0.1.

7. The radiation-emitting optoelectronic component as claimed in claim 1,
wherein
the emitted radiation (17) has a wavelength of 420 nm or greater.

8. The radiation-emitting optoelectronic component as claimed in claim 1,
wherein
the nonplanar structure (4) including the quantum well structure (5) applied thereto is overgrown with a covering layer (6, 12).

9. The radiation-emitting optoelectronic component as claimed in claim 8,
wherein
the covering layer (12) has a planar surface.

10. The radiation-emitting optoelectronic component as claimed in claim 8,
wherein
the nonplanar structure (4) and the covering layer (6, 12) are formed from electrically conductive semiconductor materials having an opposite conduction type.

11. The radiation-emitting optoelectronic component as claimed in claim 1,
wherein
the nonplanar structure (4) comprises a pyramid structure or truncated pyramid structure, a cylindrical structure or one or more strips (10).

12. The radiation-emitting optoelectronic component as claimed in claim 11,
wherein
the strip (10) has a triangular, trapezoidal or rectangular cross-sectional area transversely with respect to a strip longitudinal direction.

13. The radiation-emitting optoelectronic component as claimed in claim 11,
wherein
the strip (10) is delimited in a strip longitudinal direction by a first end face (15) and a second end face (16), which are parallel to one another.

14. The radiation-emitting optoelectronic component as claimed in claim 13,
wherein
the parallel end faces (15, 16) form a laser resonator.

15. The radiation-emitting optoelectronic component as claimed in claim 13,
wherein
the first end face (15) and the second end face (16) are crystal faces produced by epitaxial growth.

16. The radiation-emitting optoelectronic component as claimed in claim 11,
wherein
a plurality of strips (10) arranged parallel to one another are provided.

17. The radiation-emitting optoelectronic component as claimed in claim 11,
wherein
a plurality of strips (10) arranged parallel to one another are provided and a laser resonator is formed in a direction perpendicular to a longitudinal direction of the strips (10).

18. The radiation-emitting optoelectronic component as claimed in claim 17,
wherein
the strips (10) arranged parallel to one another are arranged periodically in such a way that they form a DFB laser structure.

19. The radiation-emitting optoelectronic component as claimed in claim 1,
wherein
the active zone is arranged between two waveguide layers (13, 14).

20. The radiation-emitting optoelectronic component as claimed in claim 19,
wherein
the waveguide layers (13, 14) contain AlGaN.

21. The radiation-emitting optoelectronic component as claimed in claim 1,
wherein
the optoelectronic component is a laser diode.

22. A method for producing a radiation-emitting optoelectronic component as claimed in claim 1,
comprising the method steps of:
a) providing an epitaxial surface,
b) applying a mask layer (3) to the epitaxial surface,
c) producing a nonplanar structure (4) by growing a nitride compound semiconductor material onto the epitaxial surface provided with the mask layer (3),
d) growing a quantum well structure (5) onto at least one side facet (9) of the nonplanar structure (4), and
e) growing a covering layer (6, 12).

23. The method as claimed in claim 22,
wherein
the epitaxial surface is a surface of a nitride compound semiconductor layer (2).

24. The method as claimed in claim 22,
wherein
the epitaxial surface is a surface of a substrate (1).

25. The method as claimed in claim 22,
wherein
the side facet (9) of the nonplanar structure (4) runs obliquely or perpendicularly with respect to the epitaxial surface.

26. The method as claimed in claim 22,
wherein
the mask layer (3) has a plurality of strip-type openings (11) arranged parallel.

27. The method as claimed in claim 26,
wherein
the strip-type openings (11) have a width b of 100 nm to 10 μm.

28. The method as claimed in claim 26,
wherein
the strip-type openings (11) are at a mutual distance d of 100 nm to 200 μm.

29. The method as claimed in claim 22,
wherein
the nonplanar structure (4) and the quantum well structure (5) are grown by means of metal organic vapor phase epitaxy (MOVPE).

30. The method as claimed in claim 22,
wherein
a covering layer (12) is applied which has a thickness such that it has a planar surface.
